(19) United States
(12) Patent Application Publication
(10) Pub. No.: US 2016/0005987 A1
(43) Pub. Date: Jan. 7, 2016

(54) Planar Structure Solar Cell with Inorganic Hole Transporting Material

(71) Applicant: Sharp Laboratories of America, Inc., Camas, WA (US)

(72) Inventors: Alexey Koposov, Vancouver, WA (US); Changqing Zhan, Vancouver, WA (US); Wei Pan, Vancouver, WA (US)

(21) Appl. No.: 14/320,691

(22) Filed: Jul. 1, 2014

(51) Int. Cl. H01L 51/42; H01L 51/00

(52) U.S. Cl. CPC H01L 51/4213; H01L 51/0002; H01L 51/0021; H01L 2031/0344

(57) ABSTRACT

A method is provided for forming a planar structure solar cell. Generally, the method forms a transparent conductive electrode, with a planar layer of a first metal oxide adjacent to the transparent conductive electrode. For example, the first metal oxide may be an n-type metal oxide. A semiconductor absorber layer is formed adjacent to the first metal oxide, comprising organic and inorganic materials. A p-type semiconductor hole-transport material (HTM) layer is formed adjacent to the semiconductor absorber layer, and a metal electrode is formed. adjacent to the HTM layer. In one aspect, the HTM layer is an inorganic material such as a p-type metal oxide. Some explicit examples of HTM materials include stoichiometric and non-stoichiometric molybdenum (VI) oxide, stoichiometric and non-stoichiometric vanadium (V) oxide, stoichiometric and non-stoichiometric nickel (II) oxide, and stoichiometric and non-stoichiometric copper (I) oxide. Also provide are planar solar cell devices.

### BACKGROUND OF THE INVENTION

1. Field of the Invention

This invention generally relates to solar cells and, more particularly, to a planar structure solar cell, using an inorganic hole-transport material.

2. Description of the Related Art

As evolved from dye-sensitized solar cells (DSSCs), perovskite-sensitized solar-cells have recently attracted a great deal attention with a record high efficiency breakthrough (>17%) based upon low cost organometal trihalide perovskite absorbers. It has been suggested that with the optimization of the cell structure, light absorber, and hole conducting material, this technology could advance to an efficiency that surpasses that of copper indium gallium (di)selenide (CIGS) (20%) and approaches crystalline silicon (25%). Conventional perovskite based solar cells use two common types of architecture: flat and mesoscopic. With the flat architecture, one absorber layer is deposited directly on a flat titanium oxide (TiO₂) surface forming a thin film, in a fashion similar to thin film solar cells. Such a planar heterojunction-type device comprises a planar wide bandgap n-type semiconductor material, such as TiO₂, zinc oxide (ZnO₂) etc., on a fluorine-doped tin oxide (SnO₂:F, FTO) glass substrate; a directly deposited perovskite material on the planar n-type semiconductor as the light absorber layer; an organic hole-transport material (HTM) on top of the absorber layer, and a counter electrode layer. The second approach adopts a configuration similar to solid dye-sensitized solar cells with a mesoporous semiconducting metal oxide; a perovskite material; an organic hole transporting redox material (HTM) to transport positive charges (holes) from the perovskite to the counter electrode; and a gold (Au) or platinum (Pt) counter electrode. Overall, the organic/inorganic perovskite material based solar cell combines the technical merits of solid-state dye-sensitized solar cells (ssDSCs) with thin film solar cell (TFSC) and represents the trend of solar cells development.

FIGS. 1A and 1B are, respectively, partial cross-sectional views of mesoscopic and planar perovskite solar cell structures (prior art). As depicted in the FIG. 1A, a mesostructured perovskite-based solar cell structure is composed of a FTO glass substrate 102 as the anode, a thin layer of compact TiO₂ layer 104 deposited by spray pyrolysis, followed by about 300-500 nanometers (nm) of mesoporous spin-coated TiO₂ 106, which serve both as the electron transporter and the “scaffold” on which the perovskite absorber 108 is coated using a solution based process. HTM 110 (e.g., spiro-OMeTAD) is coated over the perovskite absorber 108, and on top of the solar cell is a gold electrode 112 formed by evaporation.

The mesoporous TiO₂ electrode 106 has long been the most commonly used electron transporter material since the advent of liquid DSCs. This porous TiO₂ structure provides a sufficient internal surface area to which dye molecules can attach, and, therefore maximize light harvesting efficiency. The electron transfer from selected dyes to the porous TiO₂ electrode is not only a favored process but also is much faster than other recombination processes, making porous TiO₂ an indispensable photo anode for DSCs.

FIG. 2 is a diagram depicting electron and hole transport processes in a perovskite sensitized TiO₂ solar cell (prior art). The figure illustrates the basic working principle of the perovskite-based solar cell, which is somewhat similar to conventional ssDSCs. Excitons are generated within the organic/inorganic perovskite material through light absorption. The electrons are then injected into the TiO₂ conduction band[1], provided the lifetime of the excitons is long enough. Subsequently, hole transfer proceeds from the valence band of perovskite to the HTM [2], after which holes are transported to a metallic counter electrode via a charge “hopping” mechanisms along the HTM [3]. Following electron injection from the perovskite, competition in terms of “recapture” of injected electrons (from TiO₂) by the perovskite and HTM. (recombination processes) may occur [4 and 5]. In order to fabricate high performance perovskite solar cells, efforts should be concentrated in improving or maximizing the efficiency of processes [1], [2], and [3], while as, at the same time, minimizing the negative impact of processes [4] and [5]. “hv” refers to one photon of light.

FIG. 3 is a diagram depicting the molecular structure of 2,2′,7,7′-tetrakis(N,N-di-p-methoxyphenylamine)-9,9′-spirobifluorene (spiro-OMeTAD) (prior art). Due to the similarity of a perovskite cell to a ssDSC, most of the fabrication processes are transferable between the two. In the meantime, one of the most challenging aspects of perovskite-based solar cells development is the preparation and optimization of the HTM matrix formulation and the deposition processes as widely discussed in ssDSC technology. Although 2,2′,7,7′-tetrakis(N,N-di-p-methoxyphenylamine)-9,9′-spirobifluorene (spiro-OMeTAD) is the preferred solid-state hole transport material (ssHTM) for ssDSC so far, the development, of suitable alternatives remains one of active area of interest.

In addition to its relatively high cost, the formulation and deposition of the spiro-OMeTAD is also very complicated. In particular, the formulation and deposition method are directly related to the proper functionality of this HTM. Besides, the HTM itself and components of the formulation are extremely moisture sensitive, which restricts the environmental during formation, handling, and deposition of the spiro-OMeTAD. This also leads to moisture-sensitive final devices. On the other hand, the functionality (i.e. conductivity) of HTM arises from the selective oxidation of the tertiary amine nitrogen atoms. In the presence of oxygen, such oxidation would naturally occur over time resulting over-oxidation of the HTM that diminishes the conductivity, thus affecting the device performance over time. The moisture sensitivity and over-oxidation in an oxygen ambient environment significantly limit the application of this HTM in the present technology.

To replace the spiro-OMeTAD HTM with other types of HTM will not only lower the cost of such a perovskite cell by simplifying the device architecture, as depicted in FIG. 1B, a planar structure also eliminates the sensitivity to environment.

It would be advantageous if a planar structure perovskite solar cell could be fabricated using an inorganic HTM material different from spiro-OMeTAD.

### SUMMARY OF THE INVENTION

To address the problems with the use of spiro-OMeTAD as a hole-transport material (HTM), an inorganic HTM layer is provided that serves as electron blocking layer between a solar cell perovskite layer and counter electrode. In particular, the primary function of the HTM material in solid-state dye-sensitized solar cells (ssDSC), or solar cells originating from the sensitized architecture, is either to provide conductivity of the positive charges to the counter electrode, or when necessary, to provide a barrier between the absorber layer and counter electrode to avoid recombination of the charges on the metal/absorber interface. In the case of perovskite based solar cells, the recombination of charges at the interface between the absorber and counter electrode results in a non-performing cell. Therefore, such a blocking layer is indispensable to a planar perovskite architecture. However, this new inorganic HTM layer is not an insulator, but more like a p-type wide bandgap semiconductor that can transport holes from the perovskite to the counter electrode. Such materials include molybdenum, copper, nickel, or vanadium oxides, and they can be either sputtered or solution processed onto the top of perovskite. In addition, the deposition technique may include thermal evaporation, reactive sputtering, or the oxidation of the appropriate metal layer. The thickness of such an inorganic HTM is in the range of 1-150 nanometers.

Accordingly, a method is provided for forming a planar structure solar cell. Generally, the method forms a transparent conductive electrode, with a planar layer of a first metal oxide adjacent to the transparent conductive electrode. For example, the first metal oxide may be an n-type metal oxide. A semiconductor absorber layer is formed adjacent to the first metal oxide, comprising organic and inorganic materials. A p-type semiconductor HTM layer is formed adjacent to the semiconductor absorber layer, and a metal electrode is formed adjacent to the HTM layer. In one aspect, the HTM layer is an inorganic material. such as a p-type metal oxide.

More explicitly, the transparent conductive electrode is formed overlying a transparent substrate, with the planar layer of the first metal oxide formed overlying the transparent conductive electrode, the semiconductor absorber layer formed overlying the first metal oxide, the HTM layer formed overlying the semiconductor absorber layer, and the metal electrode formed overlying the HTM layer. Alternatively, the metal electrode is formed overlying a substrate, with the HTM layer formed overlying the metal electrode, the semiconductor absorber layer formed overlying the HTM layer, the planar layer of the first metal oxide formed overlying the semiconductor absorber layer, and the transparent conductive electrode formed overlying the first metal oxide. The architectures described above may include additional layers with different functionalities, such as might be useful for the purposes of charge separation and the prevention of recombination.

The planar layer of first metal oxide may be titanium oxide (TiO₂), tin oxide (SnO₂), zinc oxide (ZnO), niobium oxide (Nb₂O₅), tantalum oxide (Ta₂O₅), barium titanate (BaTiO₃), strontium titanate (SrTiO₃), zinc titanate (ZnTiO₃), or copper titanate (CuTiO₃).

Some explicit examples of HTM materials include stoichiometric and non-stoichiometric molybdenum (VI) oxide, stoichiometric and non-stoichiometric vanadium (V) oxide, stoichiometric and non-stoichiometric nickel (II) oxide, stoichiometric and non-stoichiometric tungsten (VI) oxide, stoichiometric and non-stoichiometric chromium (VI) oxide, and stoichiometric and non-stoichiometric copper (I) oxide.

Additional details of the above-described method and a planar structure solar cell are presented below.

### BRIEF DESCRIPTION OF THE DRAWINGS

FIGS. 1A and 1B are, respectively, partial cross-sectional views of mesoscopic and planar perovskite solar cell structures (prior art).

FIG. 2 is a diagram depicting electron and hole transport processes in a perovskite sensitized TiO₂ solar cell (prior art).

FIG. 3 is a diagram depicting the molecular structure of 2,2′,7,7′-tetrakis(N,N-di-p-methoxyphenylamine)-9,9′-spirobifluorene (spiro-OMeTAD) (prior art).

FIG. 4 is a partial cross-sectional view of a planar structure solar cell.

FIG. 5 is a partial cross-sectional view depicting a variation of the solar cell of FIG. 4.

FIGS. 6A through 6E are partial cross-section views depicting a bottom-up fabrication process.

FIGS. 7A through 7D are partial cross-section views depicting an inverted fabrication procedure.

FIG. 8 is a flowchart illustrating a method for forming a planar structure solar cell.

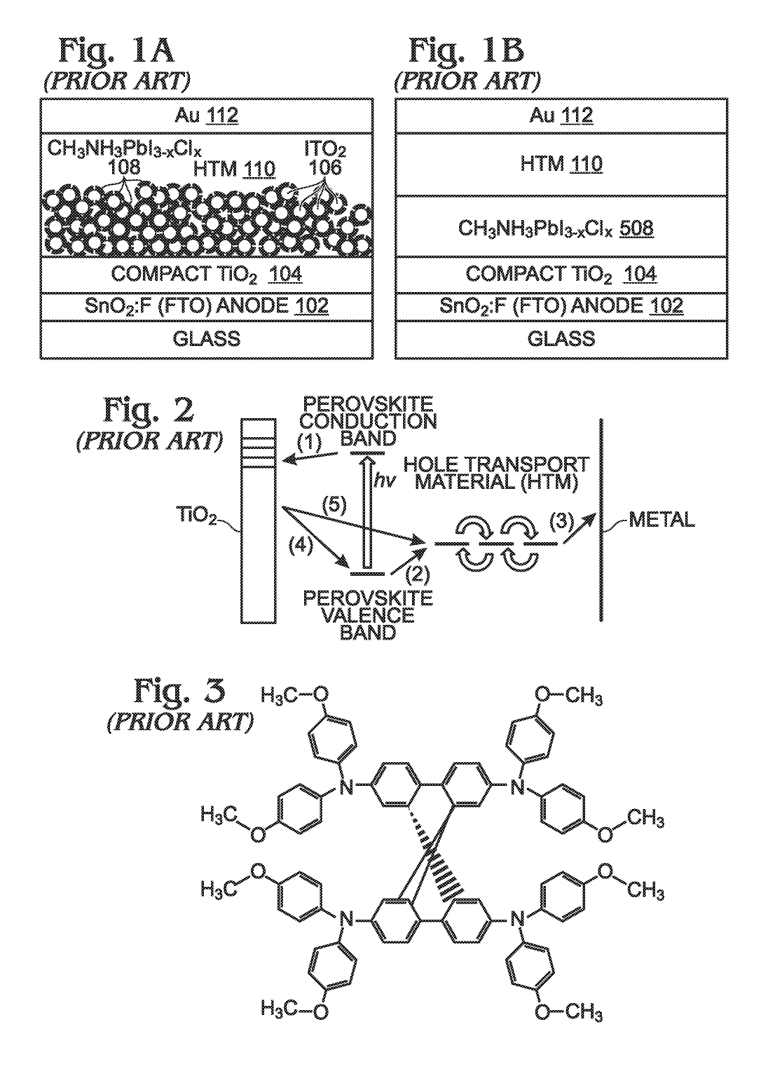

### DETAILED DESCRIPTION

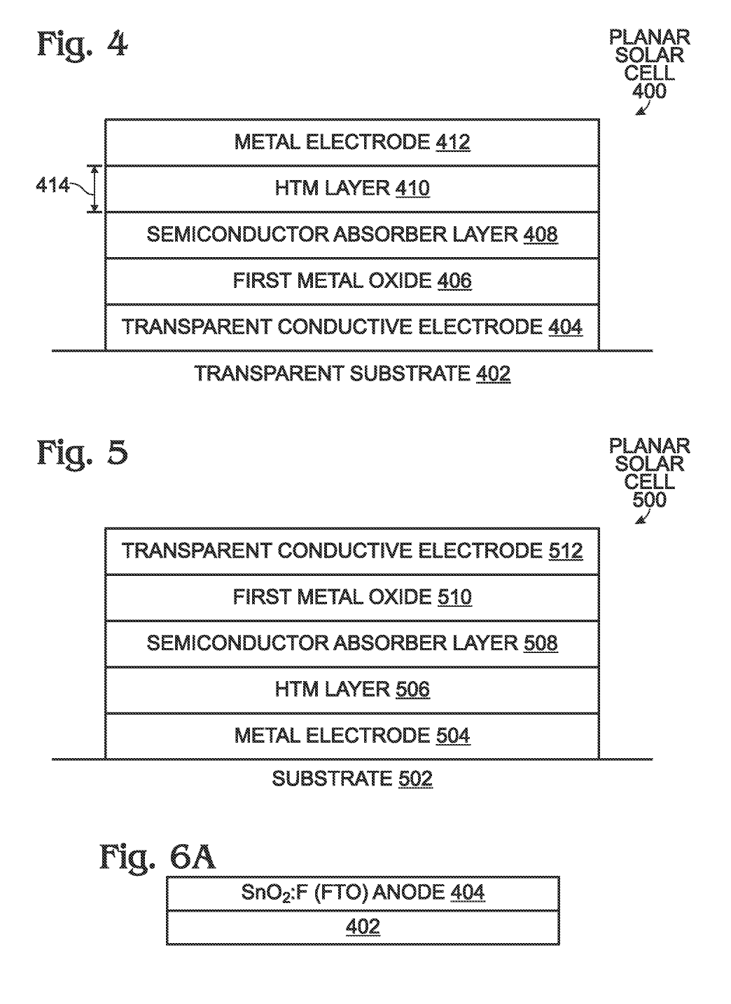

FIG. 4 is a partial cross-sectional view of a planar structure solar cell. The solar cell 400 comprises a transparent substrate 402. Silica (glass), quartz, or a plastic may be used as the transparent substrate 402. A transparent conductive electrode 404 overlies the transparent substrate 402. Fluorine-doped tin oxide (SnO₂:F) can be used as the transparent conductive electrode 404. Forms of graphene, indium. tin oxide (ITO), other conductive metal oxides, and single-walled carbon. nanotubes may also possibly be used as a transparent conductive electrode material. A planar layer of a first metal oxide 406 overlies the transparent conductive electrode 404. In one aspect, the first metal oxide 406 is an n-type metal oxide. Some examples of the first metal oxide 406 include titanium oxide MOO, tin oxide (SnO₂), zinc oxide (ZnO), niobium oxide (Nb₂O₅), tantalum oxide (Ta₂O₅), barium titanate (BaTiO₃), strontium titanate (SrTiO₃), zinc titanate (ZnTiO₃), and copper titanate (CuTiO₃). This is not an exhaustive list of possible metal oxides.

As used herein, an n-type material is an extrinsic semiconductor with a larger electron concentration than hole concentration. The phrase ‘n-type’ comes from the negative charge of the electron. In n-type semiconductors, electrons are the majority carriers and holes are the minority carriers. As opposed to n-type semiconductors, p-type semiconductors have a larger hole concentration than electron concentration. The phrase ‘p-type’ refers to the positive charge of the hole. In p-type semiconductors, holes are the majority carriers and electrons are the minority carriers.

A semiconductor absorber layer 408 overlies the first metal oxide 406, comprising organic and inorganic materials. The semiconductor absorber layer 408 has the general formula of ABX_{z}Y_{3-z};

where “A” is an organic monocation;

where B is a transition metal dication;

where X and Y are inorganic monoanions; and,

where z is in a range of 0 to 1.5.

The organic monocation “A” is typically a substituted ammonium cation with the general formula of R¹R²R³R⁴N;

where R is hydrogen, or a compound derived from linear alkanes, branched alkanes, cycloalkanes, (poly)cycloalkanes, cis- and trans-linear alkenes, cis- and trans-branched alkenes, linear alkynes, branched alkynes, (poly)alkynes, aromatic hydrocarbons, (poly)aromatic hydrocarbons, heteroarenes, (poly)heteroarenes, thiophenes, (poly)thiophenes. (poly)anilines, or combination of above-mentioned elements.

The dication B may be Pb²⁺, Sn²⁺, Cu²⁺, Ge²⁺, Zn²⁺, Ni²⁺, Fe²⁺, Mn²⁺, Eu²⁺, or Co²⁺. The monoanions X and Y are independently selected (may be the same or different materials), and may be halogenides of F-, Cl-, Br-, and I-, cyanides, or thiocyanides. The absorber material may also be a mixture or combination of the above-listed materials. In one aspect, the semiconductor absorber layer may be a perovskite material such as CH₃NH₃Pbl_{3-X}Cl_{X}.

A p-type semiconductor hole-transport material (HTM) layer 410 overlies the semiconductor absorber layer 408, and a metal electrode 412 overlies the HTM layer 410. The metal electrode may be a highly conductive metal such as silver, aluminum, copper, molybdenum, nickel, gold, or platinum. Typically, the HTM layer 410 is an inorganic material, having a thickness 414 in the range of 1 to 150 nanometers. Note: the figure is not drawn to scale. In one aspect, the HTM layer material has a bandgap greater than 3 electron volts (eV). As is well known in the art, a bandgap is the range between the valence band and the conduction band, in which electron states cannot exist. More explicitly, the bandgap can be defined as the difference in energy, as expressed in electron volts, between. the top of the valence band and the bottom of the conduction band of insulator and semiconductor materials. This is equivalent to the energy required to free an outer shell electron from its orbit about the nucleus to become a mobile charge carrier, able to move freely within a solid material. Substances with large band gaps are generally insulators, those with smaller hand gaps are semiconductors, while conductors either have very small band gaps or none, because the valence and conduction hands overlap.

Some explicit examples of HTM layer materials include stoichiometric and non-stoichiometric molybdenum (VI) oxide, stoichiometric and non-stoichiometric vanadium (V) oxide, stoichiometric and non-stoichiometric nickel (II) oxide, stoichiometric and non-stoichiometric tungsten (VI) oxide, stoichiometric and non-stoichiometric chromium (VI) oxide, and stoichiometric and non-stoichiometric copper (I) oxide. This is not an exhaustive list of possible HTM materials, as metal oxides with similar characteristics may also enable the solar cell 400.

FIG. 5 is a partial cross-sectional view depicting a variation of the solar cell of FIG. 4. Due to the use of an inorganic HTM material, the solar cell can be constructed in reverse order, with the semiconductor absorber layer formed over the HTM layer. As such, the planar structure solar cell 500 may comprise a substrate 502, which need not be transparent and which may, for example, the silicon or a metal foil. A metal electrode 504 overlies the substrate 502, and a p-type semiconductor HTM layer 506 overlies the metal electrode 504. A semiconductor absorber layer 508 overlies the HTM layer 506, a planar layer of the first metal oxide 510 overlies the semiconductor absorber layer 508, and a transparent conductive electrode 512 overlies the first metal oxide.

The solar cell of FIG. 5 may be fabricated using the same materials mentioned in the description of FIG. 4, and they are not repeated here in the interest of brevity.

As described above, a relatively thin layer of the p-type semiconductor oxide (e.g., 1 to 100 nanometers) with a large handgap may be used as the HTM material between an absorber layer comprised of hybrid organic/inorganic perovskite material and the metal counter electrode. The insertion, of such an oxide semiconductor layer into the flat heterojunction-type architecture replaces conventional organic hole transporting materials such as spiro-OMeTAD. The deposition of such a semiconductor oxide film over perovskite may be carried out though physical deposition process such as sputtering or evaporation.

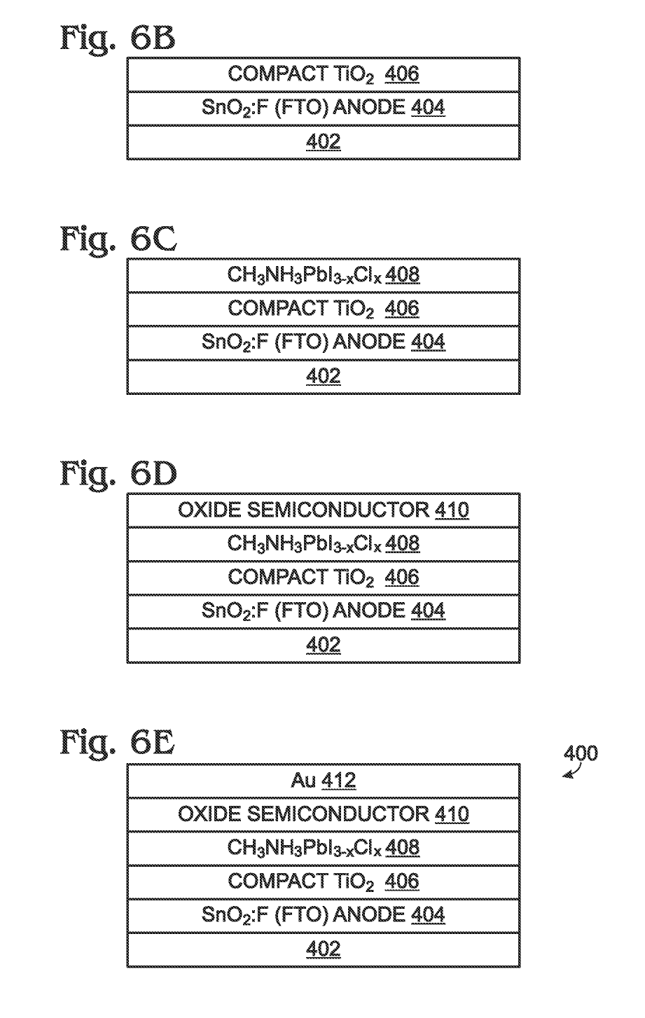

FIGS. 6A through 6E are partial cross-section views depicting a bottom-up fabrication process. A conductive transparent electrode 404 (e.g., FTO glass) is formed over a transparent substrate 402 in FIG. 5A. In FIG. 6B a compact (planar or non-mesoporous) layer of first metal oxide (TiO₂) is deposited. In FIG. 5C a semiconductor absorber layer 408 (e.g., perovskite) is formed, for example, using a deposition of lead-based halogenides followed by thermal evaporation. In FIG. 6D the HTM layer 410 (e.g., p-type semiconductor oxide) is deposited, and in FIG. 6E the metal counter electrode 412 is deposited. This bottom-up scheme is the natural carryover of an ssDSC fabrication procedure in which spire-OMeTAD is used. However, the whole architecture can be inverted if inorganic semiconductor oxides are used to replace spiro-OMeTAD, as the processing conditions for a perovskite material would be compatible with a previously deposited inorganic material, but not an organic spiro-OMeTAD material.

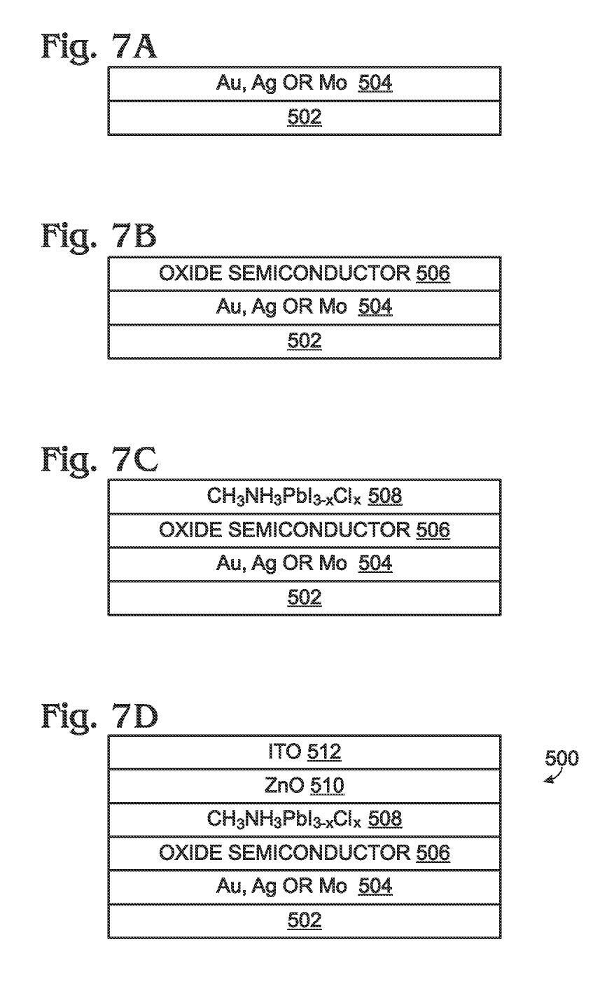

FIGS. 7A through 7D are partial cross-section views depicting an inverted fabrication procedure. For example, in FIG. 7A a metal electrode 504 is deposited on a substrate 502. In FIG. 7B an HTM layer 506 (e.g., molybdenum oxide) may be grown on top of either molybdenum itself, or a silver or gold metal electrode 504, which can be determined based on the device performance. Following the metallmolybdenum oxide, in FIG. 7C the semiconductor absorber layer 508 (e.g., perovskite material) is deposited through solution processing of precursors (lead iodide/bromide/chloride and organic ammonium bromidetiodide). The perovskite deposition can also be achieved through thermal evaporation of both precursors from dual sources. Following the perovskite layer, the first metal oxide 510 (e.g., zinc oxide) is deposited in FIG. 7D, acting as an n-type semiconductor. Finally, a transparent conducting electrode 512, such as a transparent conducting oxide (TCO), e.g., ITO, is deposited through the conventional vacuum techniques. Thus, an inverted perovskite device is realized through the benefit using conventional thin film cell fabrication methods.

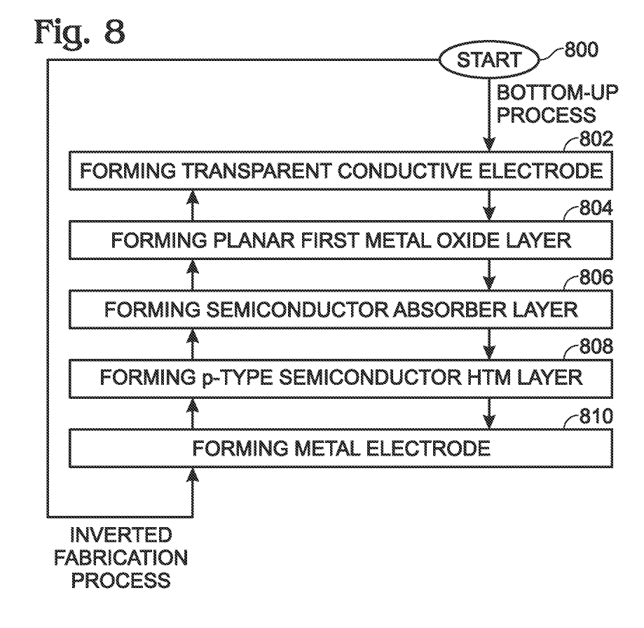

FIG. 8 is a flowchart illustrating a method for forming a planar structure solar cell. Although the method is depicted as a sequence of numbered steps for clarity, the numbering does not necessarily dictate the order of the steps. It should be understood that some of these steps may be skipped, performed in parallel, or performed without the requirement of maintaining a strict order of sequence. In some aspects, the method includes the formation of other, unnamed layers, such as might be used for improved carrier manipulation. These layers may include cadmium, sulfide, indium, selenide, or other materials with similar characteristics. The method starts at Step 800.

Step 802 forms a transparent conductive electrode. Step 804 forms a planar layer of a first metal oxide adjacent to the transparent conductive electrode. Step 806 forms a semiconductor absorber layer adjacent to the first metal oxide, comprising organic and inorganic materials. Step 808 forms a p-type semiconductor HTM layer adjacent to the semiconductor absorber layer. Step 810 forms a metal electrode adjacent to the HTM layer.

In one aspect, as described above in FIG. 4 and FIGS. 6A-6E, the above-described steps are performed in numerical order, so that Step 802 forms the transparent conductive electrode overlying a transparent substrate, Step 804 forms the planar layer of the first metal oxide overlying the transparent conductive electrode, Step 806 forms the semiconductor absorber layer overlying the first metal oxide, Step 808 forms the HTM layer overlying the semiconductor absorber layer, and Step 810 forms the metal electrode overlying the HTM layer.

Alternatively, as described above in FIG. 5 and FIGS. 7A-7D, the steps are performed in an inverted numerical order, so that Step 810 forms the metal electrode overlying a substrate, Step 808 forms the HTM layer overlying the metal electrode. Step 806 forms the semiconductor absorber layer overlying the HTM layer, Step 804 forms the planar layer of the first metal oxide overlying the semiconductor absorber layer, and Step 802 forms the transparent conductive electrode overlying the first metal oxide.

The HTM layer formed in Step 808 is a inorganic material and may be a p-type metal oxide, some examples of which include stoichiometric and non-stoichiometric molybdenum (VI) oxide, stoichiometric and non-stoichiometric vanadium (V) oxide, stoichiometric and non-stoichiometric nickel (II) oxide, stoichiometric and non-stoichiometric tungsten (VI) oxide, stoichiometric and non-stoichiometric chromium (VI) oxide, and stoichiometric and non-stoichiometric copper (I) oxide. In one aspect, the HTM layer is formed to a thickness in the range of 1 to 150 nanometers.

The planar layer of first metal oxide formed in Step 804 may be an n-type metal oxide, some examples of which include titanium oxide (TiO₂), tin oxide (SnO₂), zinc oxide (ZnO), niobium oxide (Nb₂O₅), tantalum oxide (Ta₂O₅), barium titanate (BaTiO₃), strontium titanate (SrTiO₃), zinc titanate (ZnTiO₃), and copper titanate (CuTiO₃).

A planar structure solar call and associated fabrication processes have been provided. Examples of particular materials and process steps have been presented to illustrate the invention. However, the invention is not limited to merely these examples. Other variations and embodiments of the invention will occur to those skilled in the art.

We claim:

1. A planar structure solar cell comprising:
a transparent substrate;
a transparent conductive electrode overlying the transparent substrate;
a first metal oxide having a planar top surface and a planar bottom surface overlying the transparent conductive electrode;
a semiconductor absorber layer overlying the first metal oxide planar top surface, the semiconductor absorber layer formed from a single material comprising organic and inorganic components;
a p-type inorganic semiconductor hole-transport material (HTM) layer overlying the semiconductor absorber layer; and,
a metal electrode overlying the HTM layer.

2. The solar cell of claim 1 wherein the first metal oxide is an n-type metal oxide.

3. (canceled)

4. The solar cell of claim 1 wherein the first metal oxide is selected from a group consisting of titanium oxide (TiO₂), tin oxide (SnO₂), zinc oxide (ZnO), niobium oxide (Nb₂O₅), tantalum oxide (Ta₂O₅), barium titanate (BaTiO₃), strontium titanate (SrTiO₃), zinc titanate (ZnTiO₃), and copper titanate (CuTiO₃).

5. The solar cell of claim 1 wherein the HTM layer has a thickness in a range of 1 to 150 nanometers.

6. The solar cell of claim 1 wherein the HTM layer is a material selected from a group consisting of stoichiometric and non-stoichiometric molybdenum (VI) oxide, stoichiometric and non-stoichiometric vanadium (V) oxide, stoichiometric and non-stoichiometric nickel (II) oxide, stoichiometric and non-stoichiometric tungsten (VI) oxide, stoichiometric and non-stoichiometric chromium (VI) oxide, and stoichiometric and non-stoichiometric copper (I) oxide.

7. A planar structure solar cell comprising:
a substrate;
a metal electrode overlying the substrate;
a p-type inorganic semiconductor hole-transport material (HTM) layer overlying the metal electrode;
a semiconductor absorber layer overlying the HTM layer, formed from a single material comprising organic and inorganic components;
a first metal oxide having a planar bottom surface overlying the semiconductor absorber layer, and a planar top surface; and,
a transparent conductive electrode overlying the first metal oxide planar top surface.

8. The solar cell of claim 7 wherein the first metal oxide is an n-type metal oxide.

9. (canceled)

10. The solar cell of claim 7 wherein the first metal oxide is selected from a group consisting of titanium oxide (TiO₂), tin oxide (SnO₂), zinc oxide niobium oxide (Nb₂O₅), tantalum oxide (Ta₂O₅), barium titanate (BaTiO₃), strontium titanate (SrTiO₃), zinc titanate (ZnTiO₃), and copper titanate (CuTiO₃).

11. The solar cell of claim 7 wherein the HTM layer has a thickness in a range of 1 to 150 nanometers.

12. The solar cell of claim 7 wherein the HTM layer is a material selected from a group consisting of stoichiometric and non-stoichiometric molybdenum (VI) oxide, stoichiometric and non-stoichiometric vanadium (V) oxide, stoichiometric and non-stoichiometric nickel (II) oxide, stoichiometric and non-stoichiometric tungsten (VI) oxide, stoichiometric and non-stoichiometric chromium (VI) oxide, and stoichiometric and non-stoichiometric copper (I) oxide.

13. A method for forming a planar structure solar cell, the method comprising:
forming a transparent conductive electrode;
forming a first metal oxide with a planar first surface and a planar second surface adjacent to the transparent conductive electrode;
forming a semiconductor absorber layer adjacent to the first metal oxide planar second surface, the semiconductor absorber layer formed from a single material comprising organic and inorganic components;
forming a p-type inorganic semiconductor hole-transport material (HTM) layer adjacent to the semiconductor absorber layer; and,
forming a metal electrode adjacent to the HTM layer.

14. The method of claim 13 wherein the transparent conductive electrode is formed overlying a transparent substrate;
wherein the first metal oxide planar first surface is formed overlying the transparent conductive electrode;
wherein the semiconductor absorber layer is formed overlying the first metal oxide planar second surface;
wherein the HTM layer is formed overlying the semiconductor absorber layer; and,
wherein the metal electrode is formed overlying the HTM layer.

15. The method of claim 13 wherein the metal electrode is formed overlying a substrate;
wherein the HTM layer is formed overlying the metal electrode;
wherein the semiconductor absorber layer is formed overlying the HTM layer;
wherein the planar layer of the first metal oxide planar first surface is formed overlying the semiconductor absorber layer; and,
wherein the transparent conductive electrode is formed overlying the first metal oxide planar second surface.

16. The method of claim 13 wherein forming the HTM layer includes growing a p-type metal oxide overlying the metal electrode.

17. The method of claim 13 wherein forming the first metal oxide includes the first metal oxide being selected from a group consisting of titanium oxide (TiO₂), tin oxide (SnO₂), zinc oxide (ZnO), niobium oxide (Nb₂O₅), tantalum oxide (Ta₂O₅), barium titanate (BaTiO₂), strontium titanate (SrTiO₃), zinc titanate (ZnTiO₃), and copper titanate (CuTiO₃).

18. (canceled)

19. The method of claim 13 wherein forming the first metal oxide layer includes forming an n-type first metal oxide layer.

20. The method of claim 13 wherein forming the HTM layer includes forming the HTM layer to a thickness in a range of 1 to 150 nanometers.

21. The method of claim 13 wherein forming the HTM layer includes forming the HTM layer from a material selected from a group consisting of stoichiometric and non-stoichiometric molybdenum (VI) oxide, stoichiometric and non-stoichiometric vanadium (V) oxide, stoichiometric and non-stoichiometric nickel (II) oxide, stoichiometric and non-stoichiometric tungsten (VI) oxide, stoichiometric and non-stoichiometric chromium (VI) oxide, and stoichiometric and non-stoichiometric copper (I) oxide.

22. The solar cell of claim 1 wherein the semiconductor absorber layer has the general formula of ABX_{z}Y_{3-z};
where “A” is an organic monocation;
where B is a transition metal dication;
where X and Y are inorganic monoanions; and,
where z is in a range of 0 to 1.5.

23. The solar cell of claim 7 wherein the semiconductor absorber layer has the general formula of ABX_{z}Y_{3-z};
where “A” is an organic monocation;
where B is a transition metal dication;
where X and Y are inorganic monoanions; and,
where z is in a range of 0 to 1.5.

24. The solar cell of claim 13 wherein the semiconductor absorber layer has the general formula of ABX_{z}Y_{3-z};
where “A” is an organic monocation;
where B is a transition metal dication;
where X and Y are inorganic monoanions; and,
where z is in a range of 0 to 1.5.
